(19) United States
(12) Patent Application Publication
(10) Pub. No.: US 2007/0087584 A1
(43) Pub. Date: Apr. 19, 2007

(54) Plasma doping method and plasma doping apparatus for performing the same

(75) Inventors: Gyeong-Su Keum, Suwon-si (KR); Ji-Hyun Hur, Yongin-si (KR); Jai-Hyung Won, Seoul (KR); No-Hyun Huh, Yongin-si (KR); Jae-Joon Oh, Seongnam-si (KR)

Correspondence Address: LEE & MORSE, P.C., 3141 FAIRVIEW PARK DRIVE, SUITE 500, FALLS CHURCH, VA, 22042, US

(73) Assignee: Samsung Electronics Co., Ltd.

(21) Appl. No.: 11/542,639

(22) Filed: Oct. 4, 2006

(30) Foreign Application Priority Data
Oct. 5, 2005 (KR) 2005-93301

(51) Int. Cl. H01L 21/31; H01L 21/469; H01L 29/76; H01L 29/94; H01L 31/00

(52) U.S. Cl. 438/792; 257/344; 257/408

(57) ABSTRACT

In a method of doping ions into an object, such as a substrate, using plasma, a doping gas may be provided between first and second electrodes in a chamber. An electric field may be formed between the first and the second electrodes to excite the doping gas to a plasma state. The electric field may be formed by applying a first power having a first positive electric potential and a second power having a second positive electric potential, the second positive electric potential being higher than the first positive electric potential. The electric field may be reversed in direction by blocking the second power from being applied to the second electrode. Accumulated ions on the substrate may be effectively neutralized by introducing electrons toward the substrate so that arcing generation may be prevented.

### CROSS-REFERENCE TO RELATED APPLICATIONS

This application claims priority under 35 USC § 119 to Korean Patent Application No. 2005-93301 filed on Oct. 5, 2005, the contents of which are herein incorporated by reference in their entirety.

### BACKGROUND OF THE INVENTION

1. Field of the Invention

The present invention relates to a method of doping ions into an object, such as a substrate, using plasma, and an apparatus configured to dope ions into an object, such as a substrate, using plasma. More particularly, the present invention relates to a method of doping ions into an object, such as a substrate, using plasma, in which a doping gas is excited to a plasma state and positive ions in the doping gas in a plasma state may be introduced to a substrate, and an apparatus for doping ions into an object, such as a substrate by using positive ions in a doping gas in a plasma state.

2. Description of the Related Art

A semiconductor device may be manufactured by sequentially and repeatedly performing various processes, such as a deposition process, a photolithography process, an etching process, an ion implantation process, a polishing process, a cleaning process, a drying process, etc. Recent developments include improving a variety of characteristics of the semiconductor devices, such as higher storage capacity, faster speed response, greater reliability, etc. A great deal of research has been carried out in developing ways to improve fine patterning, fine metal wiring, etc., so that semiconductor devices with improved characteristics may be realized.

In an exemplary ion implantation process, an ion-beam including a target ion may be projected onto a predetermined region of a semiconductor substrate, for implantation into the predetermined region. The ion implantation process may offer advantages since, in the predetermined region of the semiconductor substrate, the number of ions implanted and the depth of the implantation may be controlled in comparison to a thermal diffusion process.

An exemplary ion-beam implantation apparatus may include an ion source generator, a beam line chamber, and an end station chamber. An exemplary operation of such an apparatus may include the ion source generator ionizing a source gas using a thermal electron emission. The beam line chamber may introduce ions, supplied by the ion source generator, toward the end station chamber, and at least one semiconductor substrate may be in the end station chamber.

However, to develop the next generation semiconductor device having high integration and high performance, an ion beam implantation apparatus capable of generating a large amount of ions, while consuming a small amount of energy, is required. Currently, to be considered as a next generation semiconductor, it is essential to have a junction with a depth of about 100 Å to about 200 Å. Thus, an ion beam implantation apparatus may be required to have a dosage, of at least, about 2×10¹⁶ atoms/cm² while consuming energy below about 5 keV. Unfortunately, a conventional ion beam implantation apparatus may have a dosage of, at most, about 1×10¹⁵ atoms/cm², while consuming energy above about 10 keV. In this regard, the conventional ion beam implantation apparatus may not be suitable for producing the next generation semiconductor device.

Further, the depth of the junction is greatly dependent on a doping energy level. Since the conventional ion beam implantation apparatus has such a high doping energy level, the semiconductor device may have a deep junction. Thus, the conventional ion beam implantation apparatus may not be appropriate for producing the next generation semiconductor device. However, a plasma doping process has been developed.

In an exemplary plasma doping process, a doping gas may be excited to a plasma state, and ions in the plasma are introduced to a cathode. In addition, the introduced ions may be implanted into a semiconductor substrate disposed on the cathode. Since the plasma doping process may have an efficiency of at least about 10 times greater than the ion implantation process, the plasma doping process may be employed in a method for forming a dual-poly gate, as well as in other various fields and applications.

FIG. 1 illustrates a cross-sectional view of an apparatus configured to dope ions into a semiconductor substrate using plasma. FIG. 2 illustrates a microscopic picture of the semiconductor substrate damaged by arcing in the apparatus of FIG. 1. FIG. 3 illustrates a graph of an electrical potential difference between the semiconductor substrate and a platen in FIG. 1.

Referring to FIGS. 1 to 3, a platen 20, configured to support a semiconductor substrate W, may be in a plasma doping chamber 10. An anode 30 may be over the platen 20. A faraday cup 41 may be adjacent to the platen 20, and the faraday cup 41 may be connected to a dose counter 45. The faraday cup 41 may have a ring shape from a plan view. A power source 50 may be connected to the platen 20 and configured to apply a bias power to the platen 20. A shield 25 may be adjacent to the platen 20 and configured to protect the faraday cup 41.

In an exemplary operation, when the anode 30 is grounded, and a bias power is applied to the platen 20, a high electrostatic field may be formed in the plasma doping chamber 10. A doping gas in the doping chamber 10 may be excited to a plasma state, and ions in the plasma may be introduced toward the platen 20. These introduced ions may permeate into the semiconductor substrate W to be doped.

In the apparatus mentioned above, doping may not last because ions introduced to the semiconductor substrate W may be accumulated on the semiconductor substrate W. Particularly, the plasma doping apparatus may generate more than ten times the number of ions than the ion beam implantation apparatus. Accordingly, the number of ions accumulated on the semiconductor substrate W of the plasma doping apparatus may be more than ten times greater than that of the ion beam implantation apparatus. However, these accumulated ions on the semiconductor substrate W may generate charges, and may cause arcing, which may damage the semiconductor substrate W.

As illustrated in FIG. 2, circuits printed on the semiconductor substrate W may be frequently damaged by arcing. Thus, a duty ratio, which shows an actual time for applying a bias power with respect to a time period for applying a bias power, is at most 12%, in order to reduce the accumulated ions on the semiconductor substrate W and prevent possible arcing.

Additionally, as illustrated in FIG. 3, a first electric potential P1, on the semiconductor substrate W, may be higher than a second electric potential P2 on the platen 20 due to the ions accumulated on the semiconductor substrate W. Since the semiconductor substrate W may have such a small thickness, a significant electric potential difference between the semiconductor substrate W and the platen 20 may generate arcing. In such cases, when arcing is generated, the semiconductor substrate W may be damaged, and subsequent processes may be halted.

Given the desirability of improving the performance of a semiconductor device, the integrity of the semiconductor substrate has been highly evaluated. However, since the semiconductor substrate may become damaged or inaccurately processed because of the above-mentioned problems, alternative measures for resolving these problems are urgently needed.

### SUMMARY OF THE INVENTION

The present invention is therefore directed to a plasma doping method, and a plasma doping apparatus for performing the same, which substantially overcome one or more of the problems due to the limitations and disadvantages of the related art.

It is therefore a feature of an exemplary embodiment of the present invention to provide a method of doping ions into an object using plasma, which is capable of effectively doping the object with the ions.

At least one of the above and other features and advantages of the present invention may be realized by providing a method of doping ions into an object using plasma, the method may include providing a doping gas between a first electrode and a second electrode, the second electrode may support the object and may be separated from the first electrode, exciting the doping gas into a plasma state by forming an electric field between the first and the second electrodes, and reversing a direction of the electric field to dope ions in the plasma-state doping gas into the object.

Forming the electric field may include applying a first power having a first positive electric potential to the first electrode, and applying a second power having a second positive electric potential to the second electrode, the second positive electric potential may be substantially higher than the first positive electric potential.

The first power may have a positive direct current (DC) voltage.

Applying the second power to the second electrode may include applying the second power to the second electrode in pulses so as to alternately introduce the ions and the electrons in the plasma-state doping gas toward the object.

Reversing the direction of the electric field may include blocking the second power from being applied to the second electrode.

The method may include measuring a dosage of ions accelerated towards the second electrode.

The method may include neutralizing accumulated ions on the object among the ions introduced.

Neutralizing accumulated ions may include applying a second power to the second electrode and causing the electric field to reverse again.

The second power having a second positive electric potential that is the same as forming the electric field.

Neutralizing accumulated ions may include applying a first power having a first positive electric potential to the first electrode, the first positive electric potential being the same as forming the electric field.

It is therefore a feature of an exemplary embodiment of the present invention to provide an apparatus configured to dope ions into an object using plasma, and efficiently perform the above method.

At least one of the above and other features and advantages of the present invention may be realized by providing an apparatus configured to dope ions into an object using plasma. The apparatus may include a chamber into which a doping gas is provided, a first electrode and a second electrode in the chamber, the second electrode may be apart from the first electrode, and the second electrode may be configured to support the object, and a power supply may be configured to operate in a first mode and a second mode, wherein in the first mode, the power supply may supply power to the first and second electrodes in a manner that forms an electric field between the first and the second electrodes, and in the second mode, the power supply may supply power to the first and second electrodes in a manner such that a direction of the electric field is reversed.

The power supply may include a first power source configured to apply a first power having a first positive electric potential to the first electrode, and a second power source configured to apply a second power having a second positive electric potential to the second electrode, the second positive electric potential may be substantially higher than the first positive electric potential.

The second power source may include a pulse generator configured to apply the second power in pulses to alternately introduce ions and electrons in the plasma-state doping gas toward the object.

The first power may have a positive DC voltage.

The apparatus may include a gas supply unit configured to supply the doping gas into the chamber. The apparatus may include a vacuum unit configured to control an internal pressure of the chamber. The apparatus may include a dose counting unit. The dose counting unit may include a faraday cup and a dose counter. The apparatus may include a shield ring which is over the faraday cup. The dose counting unit may be adjacent to the second electrode.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a cross-sectional view of an apparatus configured to dope ions into a semiconductor substrate using plasma;

FIG. 2 illustrates a microscopic picture of the semiconductor substrate damaged by arcing in the apparatus illustrated in FIG. 1;

FIG. 3 illustrates a graph of an electrical potential difference between the semiconductor substrate and the platen illustrated in FIG. 1;

FIG. 4 illustrates a cross-sectional view of an apparatus configured to dope ions into a substrate using plasma in accordance with an exemplary embodiment of the present invention;

FIG. 5 illustrates a graph of a first power applied to a first electrode illustrated in FIG. 4 in accordance with an exemplary embodiment of the present invention;

FIG. 6 illustrates a graph of a second power applied to a second electrode illustrated in FIG. 4 in accordance with an exemplary embodiment of the present invention;

FIG. 7 illustrates a graph of an electrical potential difference between the semiconductor substrate and the second electrode in FIG. 4 illustrated in accordance with an exemplary embodiment of the present invention; and

FIG. 8 illustrates a flow chart of a method for counting a dosage of ions and a plasma doping method in accordance with an exemplary embodiment of the present invention.

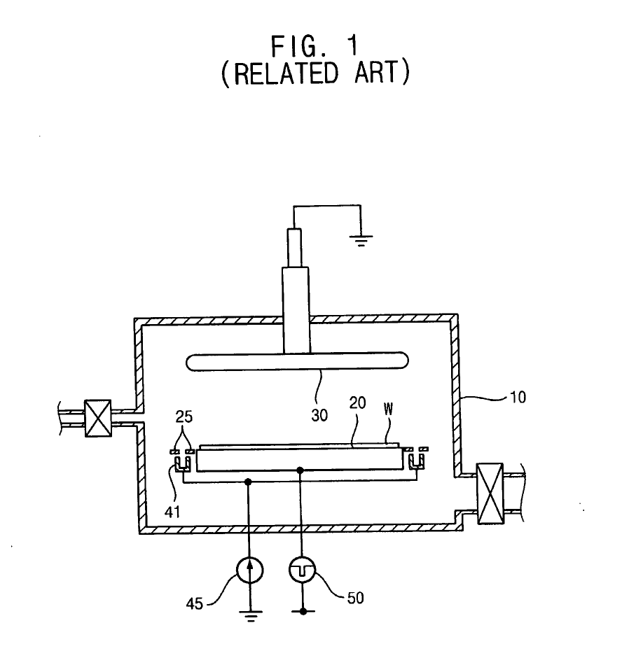

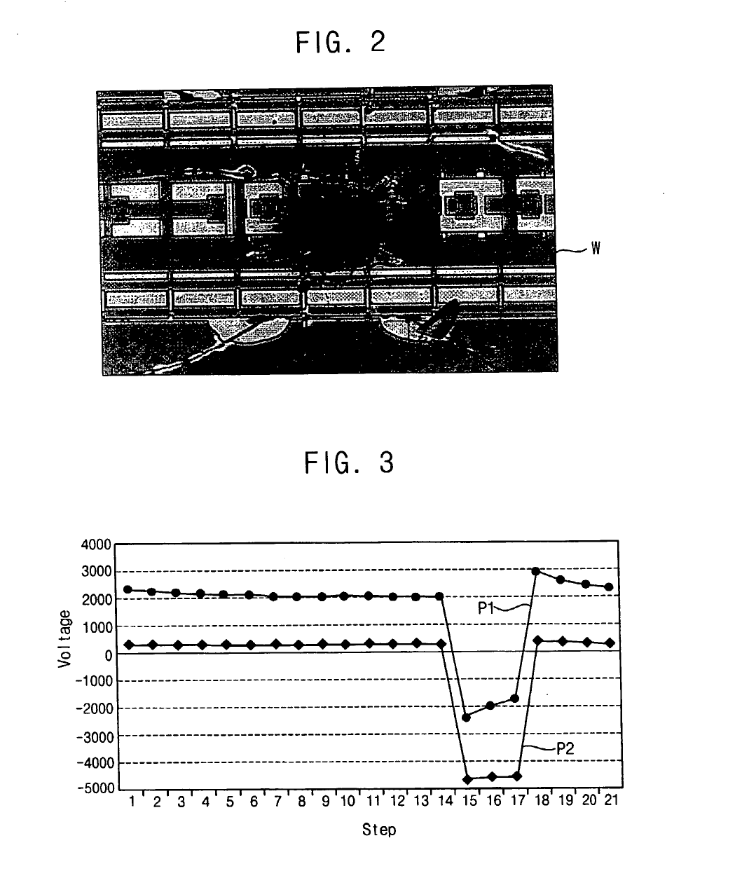

### DETAILED DESCRIPTION OF THE INVENTION

The present invention will now be described more fully hereinafter with reference to the accompanying figures, in which exemplary embodiments of the invention are illustrated. The present invention may, however, be embodied in different forms and should not be construed as limited to the exemplary embodiments set forth herein. Rather, these embodiments are provided so that this disclosure will be thorough and complete, and will fully convey the scope of the present invention to those skilled in the art. In the accompanying drawings, the dimensions and relative dimensions of elements, layers, and regions may be exaggerated for clarity of illustration.

It will be understood that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. In addition, it will also be understood that when an element or layer is referred to as being “between” two elements or layers, it can be the only element or layer “between” the two elements or two layers, or one or more intervening elements or layers may also be present.

Like reference numerals refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer and/or section from another element, component, region, layer and/or section. Thus, a first element, component, region, layer and/or section discussed below could be termed a second element, component, region, layer and/or section without departing from the teachings of the present invention.

Spatially relative terms, such as “beneath,” “below,” “under,” “lower,” “above,” “upper”, and the like, may be used herein for ease of description to describe a relationship of an element(s) or feature(s) to another element(s) or feature(s) as illustrated in the accompanying figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations), and the spatially relative descriptors used herein interpreted accordingly. Further, it will be understood that when an element or layer is referred to as being, for example, “under” another element or layer, it can be directly “under”, or one or more intervening elements or layers may also be present.

The terminology used herein is for the purpose of describing particular exemplary embodiments only, and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the present invention are described herein with reference to cross-section illustrations that are schematic illustrations of exemplary embodiments (and intermediate structures) of the present invention. As such, variations from the shapes of the illustrations as a result, for example, of manufacturing techniques and/or tolerances, are to be expected. Thus, exemplary embodiments of the present invention should not be construed as limited to the particular shapes of regions illustrated herein, but are to include deviations in shapes that result, for example, from manufacturing. For example, an implanted region illustrated as a rectangle, will, typically, have rounded or curved features and/or a gradient of implant concentration at its edges, rather than a binary change from implanted to non-implanted region. Likewise, a buried region formed by implantation may result in some implantation in the region between the buried region and the surface through which the implantation takes place. Thus, the regions illustrated in the figures are schematic in nature, and their shapes are not intended to illustrate the actual shape of a region of a device, and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art, and will not be interpreted in an idealized or overly formal sense, unless expressly so defined herein.

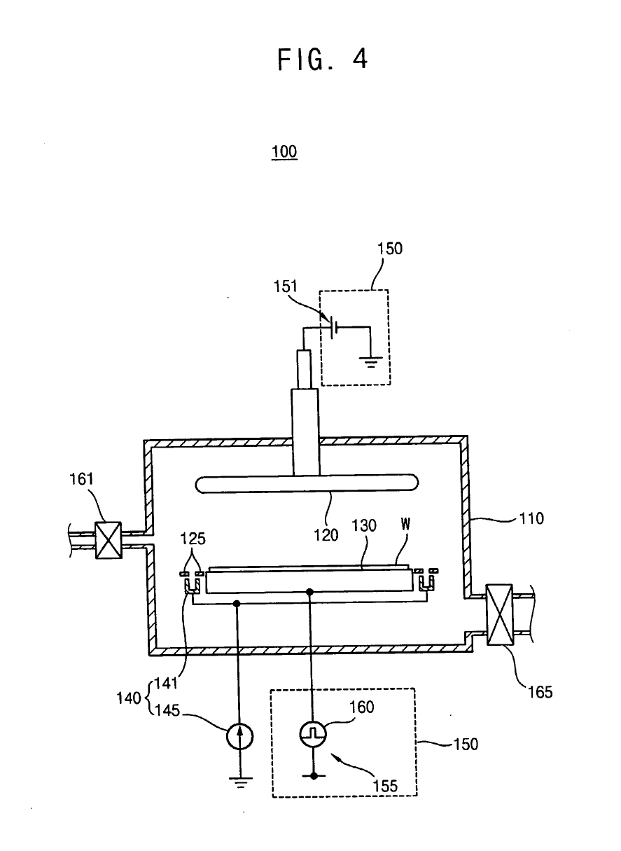

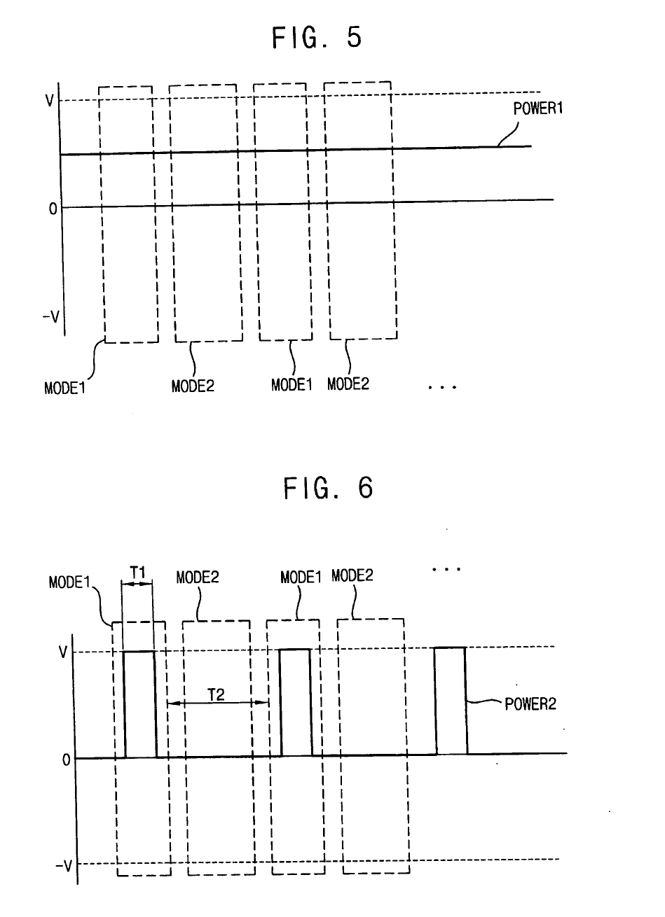

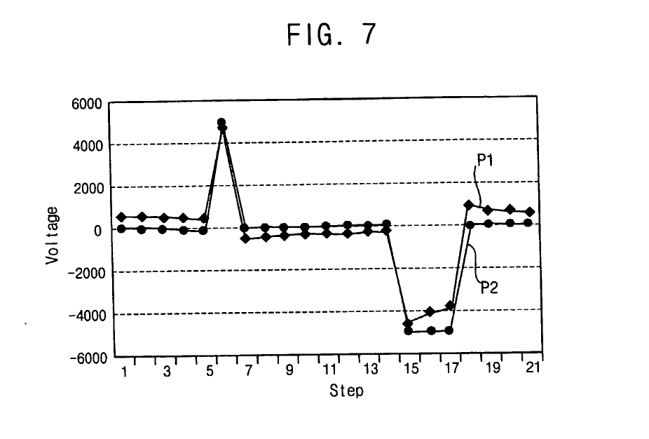

FIG. 4 illustrates a cross-sectional view of a plasma doping apparatus in accordance with an exemplary embodiment of the present invention. FIG. 5 illustrates a graph of a first power applied to a first electrode illustrated in FIG. 4. FIG. 6 illustrates a graph of a second power applied to a second electrode illustrated in FIG. 4, and FIG. 7 illustrates a graph of an electric potential difference between the semiconductor substrate and the second electrode illustrated in FIG. 4.

Referring to FIG. 4, a plasma doping apparatus 100 may include a chamber 110, a first electrode 120, a second electrode 130, a dose counting unit 140, and a power supply 150. The dose counting unit 140 may include a faraday cup 141 and a dose counter 145. The power supply 150 may include a first power source 151 and a second power source 155. The second power source 155 may include a pulse generator 160. The plasma doping apparatus 100 may further include a shielding ring 125, a gas supplying unit 161, and a vacuum unit 165. The plasma doping apparatus 100 may serve as an apparatus for implanting ions into an object, such as a semiconductor substrate W.

The chamber 110 may provide a sealed space configured to perform a plasma doping process. The gas supply unit 161 may be on one side portion of the chamber 110, and configured to supply a doping gas into the sealed space. The vacuum unit 165 may be on another side portion of the chamber 110, and configured to evacuate the sealed space. Examples of the doping gas may include a boron trifluoride (BF₃) gas, a nitrogen (N₂) gas, an argon (Ar) gas, a phosphine (PH₃) gas, an arsine (AsH₃) gas, etc.

The doping gas may be repeatedly supplied into the sealed space of the chamber 110 so that the plasma doping process may be repeatedly performed. A mass flow controller (MFC) (not illustrated) may be at the gas supply unit 161 to control a flow rate of the doping gas provided into the sealed space.

The second electrode 130 may be at a lower portion of the chamber 110 and configured to support an object such as a semiconductor substrate W. The first electrode 120 may be over the second electrode 130.

The second electrode 130 may include a conductive material. The second electrode 130 may have, for example, a circular plate shape. The second electrode 130 may further include lift pins (not illustrated). The lift pins may be configured to support the semiconductor substrate W therein and may be connected to a generator (not illustrated) configured to revolve the second electrode 130.

The first electrode 120 may be over the second electrode 130 and face the semiconductor substrate W on the second electrode 130. The first electrode 120 may have an area substantially the same as that of the second electrode 130 from a plan view.

The dose counting unit 140 may be adjacent to the second electrode 130. The dose counting unit 140 may serve as a device that measures a dosage of ions in plasma. The faraday cup 141 may be adjacent to the second electrode 130 and may have a ring shape from a plan view. The dose counter 145 may measure current generated by collected ions in the faraday cup 141 and may calculate a dosage of the collected ions in the faraday cup 141 from the measurement results. The shield ring 125 may be over the faraday cup 141 to protect the faraday cup 141. The faraday cup 141 may have a variety of shapes and positions other than the shape and position illustrated in FIG. 4. Accordingly, those skilled in the art may easily modify the faraday cup 141 to have a shape and position other than that illustrated in FIG. 4.

The power supply 150 may be connected to the first and the second electrodes 120 and 130 and may repeatedly perform a doping process and a neutralization process. The power supply may be operated in a first mode MODE1 and in a second mode MODE2. In the first mode MODE1, an electric field may be formed, between the first electrode 120 and the second electrode 130, to excite a doping gas to a plasma state. In the second mode MODE2, a direction of the electric field may be reversed so that ions in the plasma-state doping gas may be doped into the semiconductor substrate W.

The first power source 151 may be connected to the first electrode 120, and the second power source 155 may be connected to the second electrode 130. A particular structure of the power supply is not illustrated in FIG. 4, but those skilled in the art may easily configure a structure of the power supply based on the description of the present invention discussed herein.

Referring to FIG. 5, the first power source 151 may be configured to supply a first power POWER1 to the first electrode 120 having a positive electric potential. The first power POWER1 may have a direct current (DC) voltage, and may be supplied to the first electrode 120 in the first mode MODE1, and in the second mode MODE2. That is, the first power POWER1 may be continuously supplied to the first electrode.

Referring to FIG. 6, the second power source 155 may be configured to supply a second power POWER2 to the second electrode 130 in pulses. Thus, the second power source 155 may further include the pulse generator 160. The second power POWER2 may be supplied to the second electrode 130 with a voltage of about 100 V to about 50 kV for a time duration of T1, which may be about 1 μs to about 50 μs. The provided pulse frequency of the second power POWER2 may be about 100 Hz to about 2 kHz.

The second power source 155 may be operated in the first mode MODE1 and in the second mode MODE2. In the first mode MODE1, the second power POWER2, which may have a positive electric potential substantially higher than that of the first power POWER2, may be supplied to the second electrode 130. In the second MODE2, the second power POWER2 may be blocked from being supplied to the second electrode 130.

In the first mode MODE1, when the second power POWER2 may be supplied to the second electrode 130, the second electrode 130 may serve as an anode, and the first electrode 120 may serve as a cathode. Thus, a high electric field may be formed between the first and the second electrodes 120 and 130, and the doping gas exposed to the high electric field may be excited to a plasma state.

In the second mode MODE2, when the second power POWER2 may be blocked from being supplied to the second electrode 130, the first electrode 120 may serve as an anode, and the second electrode 130 may serve as a cathode. Thus, the electric field formed between the first and the second electrodes 120 and 130 may be reversed in direction, compared to the electric field formed in the first mode MODE1, and the ions in the plasma-state doping gas may be accelerated toward the second electrode 130, which may be doped into the semiconductor substrate W for a predetermined time T2. Unfortunately, some of the ions of the total ions accelerated toward the second electrode 130 may not be doped into the semiconductor substrate W and may accumulate on the semiconductor substrate W. However, the present invention resolves this problem, as discussed in greater detail below.

The second power POWER2 may be applied again to the second electrode 130 (that is, when the second mode MODE2 changes into the first mode MODE1), and the electric field between the first and the second electrodes 120 and 130 may be reversed again in direction. The doping gas may be excited to a plasma state and maintained in the plasma state, and electrons in the plasma-state doping gas may be accelerated toward the second electrode 130, which serves as an anode. The accelerated electrons may be coupled to the accumulated ions on the semiconductor substrate W so that the accumulated ions may be neutralized. Thus, the accumulated ions on the semiconductor substrate W may be prevented from generating arcing.

Referring to FIG. 7, in the plasma doping apparatus 100 in accordance with an exemplary embodiment of the present invention, a first electric potential P1 on a top surface of the semiconductor substrate W may be similar to, or substantially the same as, a second electric potential P2 of the second electrode 130. When a difference between the first and second electric potentials P1 and P2 is reduced, the second mode MODE2 may last for a predetermined time without generating arcing. Thus, a duty ratio may be increased.

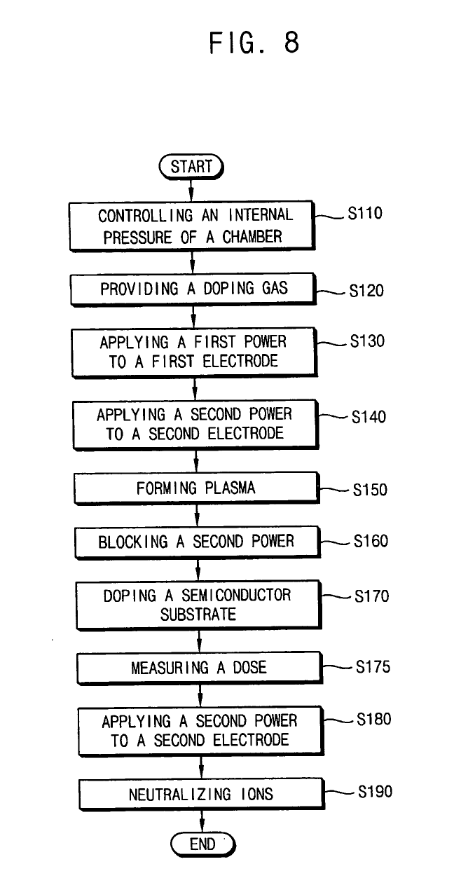

Hereinafter, a dose counting method using the plasma doping apparatus will be described with reference to FIGS. 4 to 8.

Referring to FIGS. 4 to 8, in step S110, the vacuum unit 165 may be operated to vacuumize the chamber 110. The chamber 110 may be under a vacuum level of about 500 mTorr to about 1 Torr.

When the chamber 110 is under a desired pressure, in step S120, the gas supply unit 161 may be operated to supply the doping gas into the chamber 110. The doping gas may be supplied into the chamber 110 under a constant pressure and at a constant flow rate. The doping gas may be, for example, boron trifluoride (BF₃) gas, nitrogen (N₂) gas, argon (Ar) gas, phosphine (PH₃) gas, arsine (ASH₃) gas, diborane (B₂H₆) gas, etc. The doping gas may be substantially, uniformly diffused between the first and the second electrodes 120 and 130.

In step S130, a first power POWER1 having a first positive electric potential may be applied to the first electrode 120.

In step S140, a second power POWER2, having a second positive electric potential may be applied to the second electrode 130 to form an electric field. The second positive electric potential may be substantially higher than the first positive electric potential,

The first power POWER1 may have a DC voltage, and the second power POWER2 may be supplied to the second electrode 130 in pulses. The second power POWER2 may be applied to the second electrode 130 with a voltage of about 100 V to about 50 kV for a time duration T1, which is about 1 μs to about 50 μs. An applied pulse frequency of the second power POWER2 may be about 100 Hz to about 2 kHz.

As the first power POWER1 having the first positive electric potential may be applied to the first electrode 120, and the second power POWER2 having the second positive electric potential, which may be substantially higher than the first positive electric potential, may be applied to the second electrode 130, a high electric field may be formed between the first and the second electrodes 120 and 130.

In step S150, the doping gas may be exposed to the high electric field, and excited to a plasma state. The second electrode 130 may serve as an anode, and the first electrode 120 may serve as a cathode. Electrons in the plasma-state doping gas may be accelerated to the second electrode 130 serving as the anode. Here, acceleration of the electrons may occur with the generation of the plasma.

In step S160, when the second power POWER2 is blocked from being applied to the second electrode 130, the first electrode 120 may serve as an anode and the second electrode 130 may serve as a cathode. Thus, the electric field formed between the first and second electrodes 120 and 130 may be reversed in direction, compared to those in steps S140 and S150, and ions in the plasma-state doping gas may be accelerated toward the second electrode 130, which may be doped into the semiconductor substrate W for a predetermined time T2 in step S170.

In step S175, a dosage of the accelerated ions toward the second electrode 130 may be measured.

In step S180, the second power POWER2 may be applied again to the second electrode 130, and the electric field between the first and the second electrodes 120 and 130 may be reversed again in direction. The doping gas may be excited to a plasma state and maintained in the plasma state and electrons in the plasma-state doping gas may be accelerated toward the second electrode 130 serving as an anode. In step S190, the accelerated electrons may be coupled to the accumulated ions on the semiconductor substrate W so that the accumulated ions may be neutralized. Thus, the generation of arcing due to the accumulated ions on the semiconductor substrate W may be prevented.

After the ions accumulated on the semiconductor substrate W are neutralized, the steps S150, S160, S170, S180 and S190 may be repeatedly carried out, and accordingly the doping process and the neutralization process may be repeatedly performed.

In other plasma doping methods, the doping process may not last due to ions accumulated on a semiconductor substrate. However, in the plasma doping method in accordance with an exemplary embodiment of the present invention, the positive DC voltage may be applied to the first electrode 120 and the positive pulse voltage may be applied to the second electrode 130 so that the electric field between the first and the second electrodes 120 and 130 may be repeatedly reversed in direction. Accordingly, as the direction of the electric field may be repeatedly reversed, the doping process, and the neutralization process, may be repeated. Thus, a pause amid the doping process (i.e., a stand-by period until the accumulated ions on the semiconductor substrate W are removed from the chamber) may be reduced so that the total duration of time to complete the doping process may also be reduced, thereby increasing the duty ratio.

According to the exemplary embodiments of the present invention, the accumulated ions on an object, such as a semiconductor substrate, may be promptly and sufficiently removed so that a doping yield may be greatly improved and doping failure from arcing may be prevented.

According to the present invention, accumulated ions on an object, such as a semiconductor substrate, may be promptly and sufficiently removed so that a doping process may be successfully carried out for a lengthy period of time and doping failure from arcing may be effectively prevented. Thus, a next generation semiconductor device having superior characteristics may be manufactured.

The foregoing is illustrative of the present invention and is not to be construed as limiting thereof. Although exemplary embodiments of the present invention have been described, those skilled in the art will readily appreciate that many modifications are possible in the exemplary embodiments without materially departing from the novel teachings and advantages of the present invention. Accordingly, all such modifications are intended to be included within the scope of the present invention as defined in the claims. Therefore, it is to be understood that the foregoing is illustrative of the present invention and is not to be construed as limited to the specific exemplary embodiments disclosed, and that modifications to the disclosed exemplary embodiments, as well as other exemplary embodiments, are intended to be included within the scope of the appended claims.

Exemplary embodiments of the present invention have been disclosed herein, and although specific terms are employed, they are used and are to be interpreted in a generic and descriptive sense only, and not for purpose of limitation. Accordingly, it will be understood by those of ordinary skill in the art that various changes in form and details may be made without departing from the spirit and scope of the present invention as set forth in the following claims.

What is claimed is:

1. A method of doping ions into an object using plasma, comprising:
providing a doping gas between a first electrode and a second electrode, the second electrode supporting the object and being separated from the first electrode;
exciting the doping gas into a plasma state by forming an electric field between the first and the second electrodes; and
reversing a direction of the electric field to dope ions in the plasma state doping gas into the object.

2. The method as claimed in claim 1, wherein forming the electric field includes:
applying a first power having a first positive electric potential to the first electrode, and
applying a second power having a second positive electric potential to the second electrode, the second positive electric potential being substantially higher than the first positive electric potential.

3. The method as claimed in claim 2, wherein the first power has a positive direct current (DC) voltage.

4. The method as claimed in claim 2, wherein applying the second power to the second electrode includes applying the second power to the second electrode in pulses so as to alternately introduce the ions and the electrons in the plasma state doping gas toward the object.

5. The method as claimed in claim 2, wherein reversing the direction of the electric field includes blocking the second power from being applied to the second electrode.

6. The method as claimed in claim 1, including measuring a dosage of ions accelerated toward the second electrode.

7. The method as claimed in claim 1, including neutralizing accumulated ions on the object among the ions introduced.

8. The method as claimed in claim 7, wherein neutralizing accumulated ions includes applying a second power to the second electrode and causing the electric field to reverse again.

9. The method as claimed in claim 8, wherein the second power having a second positive electric potential is the same as forming the electric field.

10. The method as claimed in claim 7, wherein neutralizing accumulated ions includes applying a first power having a first positive electric potential to the first electrode, the first positive electric potential being the same as forming the electric field.

11. An apparatus for doping ions into an object using plasma, comprising:
a chamber into which a doping gas is provided;
a first electrode and a second electrode in the chamber, the second electrode being apart from the first electrode, the second electrode being configured to support the object; and
a power supply configured to operate in a first mode and a second mode, wherein in the first mode, the power supply supplies power to the first and second electrodes in a manner that forms an electric field between the first and the second electrodes, and in the second mode, the power supply supplies power to the first and second electrodes in a manner such that a direction of the electric field is reversed.

12. The apparatus as claimed in claim 11, wherein the power supply includes:
a first power source configured to apply a first power having a first positive electric potential to the first electrode; and
a second power source configured to apply a second power having a second positive electric potential to the second electrode, wherein the second positive electric potential is substantially higher than the first positive electric potential.

13. The apparatus as claimed in claim 12, wherein the second power source includes a pulse generator configured to apply the second power in pulses to alternately introduce ions and electrons in the plasma state doping gas toward the object.

14. The apparatus as claimed in claim 12, wherein the first power has a positive DC voltage.

15. The apparatus as claimed in claim 11, further comprising a gas supply unit configured to supply the doping gas into the chamber.

16. The apparatus as claimed in claim 11, further comprising a vacuum unit configured to control an internal pressure of the chamber.

17. The apparatus as claimed in claim 11, further comprising a dose counting unit.

18. The apparatus as claimed in claim 17, wherein the dose counting unit includes a faraday cup and a dose counter.

19. The apparatus as claimed in claim 18, wherein a shield ring is over the faraday cup.

20. The apparatus as claimed in claim 18, wherein the dose counting unit is adjacent to the second electrode.
